(19) United States
(12) Patent Application Publication
(10) Pub. No.: US 2021/0083698 A1
(43) Pub. Date: Mar. 18, 2021

(54) SIGNAL PROCESSING APPARATUS AND SIGNAL PROCESSING METHOD

(71) Applicant: HUAWEI TECHNOLOGIES CO., LTD., Shenzhen (CN)

(72) Inventors: Junpeng WANG, Xi'an (CN); Tengteng JI, Xi'an (CN); Yugui XUE, Shenzhen (CN); Caixia CUI, Shanghai (CN)

(21) Appl. No.: 17/104,535

(22) Filed: Nov. 25, 2020

Related U.S. Application Data
(63) Continuation of application No. PCT/CN2018/088759, filed on May 28, 2018.

(51) Int. Cl. H04B 1/04; H04B 1/00

(52) U.S. Cl. CPC H04B 1/04; H04B 1/0007; H04B 2001/307; H04B 2001/0416; H04B 1/0042

(57) ABSTRACT

Example signal processing apparatus and signal processing methods are described. One example signal processing apparatus includes a signal matching circuit, a first signal processing branch, and a second signal processing branch. An output end of the signal matching circuit is separately coupled to an input end of the first signal processing branch and an input end of the second signal processing branch, and an output end of the first signal processing branch is coupled to the input end of the second signal processing branch.

### CROSS-REFERENCE TO RELATED APPLICATIONS

This application is a continuation of International Application No. PCT/CN2018/088759, filed on May 28, 2018, the disclosure of which is hereby incorporated by reference in its entirety.

### TECHNICAL FIELD

This application relates to the field of communications technologies, and in particular, to a signal processing apparatus and a signal processing method.

### BACKGROUND

With continuous development of modern microwave communications technologies, communication environments become increasingly complex, and a possibility of interference between signals becomes increasingly higher.

When an interfering signal interacts with a wanted signal, a non-linear intermodulation product is generated. If the non-linear intermodulation product falls within a frequency band range of the wanted signal, and is in a same band with the signal, a filter commonly used for filtering out the interfering signal cannot filter out the non-linear intermodulation product, and the non-linear intermodulation product always affects quality of the wanted signal.

Therefore, how to perform effective anti-interference processing on the non-linear intermodulation product becomes a hot research subject.

### SUMMARY

This application provides a signal processing apparatus and method to resolve a problem of how to perform effective anti-interference processing on a non-linear intermodulation product.

According to a first aspect of embodiments of this application, a signal processing apparatus is disclosed. The apparatus includes: a signal matching circuit, a first signal processing branch, and a second signal processing branch, where an output end of the signal matching circuit is separately coupled to an input end of the first signal processing branch and an input end of the second signal processing branch, and an output end of the first signal processing branch is coupled to the input end of the second signal processing branch;

the signal matching circuit is configured to: separately obtain a first to-be-processed signal and a second to-be-processed signal based on an input signal, input the first to-be-processed signal to the first signal processing branch, and input the second to-be-processed signal to the second signal processing branch;

the first signal processing branch is configured to filter the first to-be-processed signal, to obtain an interference canceled signal; and input the interference canceled signal to the second signal processing branch, where the interference canceled signal includes a non-linear intermodulation product; and

the second signal processing branch is configured to collect envelope information in the second to-be-processed signal, and generate, based on the envelope information and the interference canceled signal, a target signal in which the non-linear intermodulation product is canceled out.

In the apparatus described in the first aspect, the second signal processing branch collects the envelope information of the unfiltered second to-be-processed signal, and the non-linear intermodulation product is canceled out based on the envelope information and the interference canceled signal obtained after the first signal processing branch performs filtering processing, to obtain the target signal. Therefore, effective anti-interference processing is performed on the non-linear intermodulation product to some extent, thereby improving signal quality.

In a feasible implementation, the second signal processing branch may specifically include; an envelope detecting circuit, a first analog-to-digital conversion circuit, and a digital processing circuit, where the output end of the signal matching circuit is coupled to an input end of the envelope detecting circuit, an output end of the envelope detecting circuit is coupled to an input end of the first analog-to-digital conversion circuit, and an output end of the first analog-to-digital conversion circuit and the output end of the first signal processing branch are separately coupled to an input end of the digital processing circuit;

the envelope detecting circuit is configured to collect the envelope information in the second to-be-processed signal, and input the envelope information to the first analog-to-digital conversion circuit;

the first analog-to-digital conversion circuit is configured to perform first analog-to-digital conversion processing based on the envelope information, to obtain a digital envelope signal; and input the digital envelope signal to the digital processing circuit; and

the digital processing circuit is configured to obtain, based on the interference canceled signal and the digital envelope signal, the target signal in which the non-linear intermodulation product is canceled out.

It can be learned that, through implementation of the foregoing feasible implementation, the envelope detecting circuit may effectively collect the envelope information in the second to-be-processed signal, and input the envelope information to the first analog-to-digital conversion circuit for analog-to-digital conversion, to convert the envelope information into digital envelope information in a digital domain; and then the digital envelope information is input to the digital processing circuit for digital processing, to cancel out the non-linear intermodulation product in the digital domain, thereby improving the signal quality and accuracy of collecting the envelope information.

In a feasible implementation, the digital processing circuit includes: a squaring circuit, a canceling and solving circuit, an addition circuit, and a hard decision circuit, where the output end of the first analog-to-digital conversion circuit is coupled to an input end of the squaring circuit; an output end of the squaring circuit, an output end of the hard decision circuit, and an output end of the addition circuit are separately coupled to an input end of the canceling and solving circuit; an output end of the canceling and solving circuit and the output end of the first signal processing branch are separately coupled to an input end of the addition circuit; and the output end of the addition circuit is coupled to an input end of the hard decision circuit;

the addition circuit is configured to separately input a target signal to the canceling and solving circuit and the hard decision circuit;

the hard decision circuit is configured to perform error eliminating processing on the target signal based on a preset threshold condition, to obtain an error eliminated signal; and input the error eliminated signal to the canceling and solving circuit;

the squaring circuit is configured to square the digital envelope signal, to obtain a squared signal; and input the squared signal to the canceling and solving circuit;

the canceling and solving circuit is configured to obtain, based on the squared signal, the target signal, and the error eliminated signal, an intermediate signal used to cancel out the non-linear intermodulation product, and input the intermediate signal to the addition circuit; and

the addition circuit is further configured to obtain, based on the interference canceled signal and the intermediate signal, the target signal in which the non-linear intermodulation product is canceled out.

It should be clarified that, a signal generated by the addition circuit is the target signal. As long as the signal processing apparatus is working, input signals may be continuously input to the signal processing apparatus. Therefore, when the signal processing apparatus starts to work, the first signal processing branch may generate the interference canceled signal, the squaring circuit may generate the squared signal, the canceling and solving circuit inputs the squared signal as the intermediate signal to the addition circuit, and the addition circuit generates the target signal based on the intermediate signal and the interference canceled signal. However, in this case, an effect of canceling out an interference intermodulation product in the target signal is relatively poor. In this case, the addition circuit inputs the target signal to the hard decision circuit and the canceling and solving circuit, so that the hard decision circuit performs error elimination on the target signal, to obtain the error eliminated signal, and inputs the error eliminated signal to the canceling and solving circuit. The canceling and solving circuit then performs canceling and solving based on the received target signal, error eliminated signal, and squared signal, to obtain the intermediate signal used to cancel out the non-linear intermodulation product. The addition circuit may perform synthesis based on the intermediate signal and the received interference canceled signal, to obtain the target signal in which the non-linear intermodulation product is canceled out.

In a feasible implementation, after the target signal in which the non-linear intermodulation product is canceled out is obtained, the addition circuit may further input the target signal in which the non-linear intermodulation product is canceled out to the hard decision circuit and the canceling and solving circuit, to perform next signal processing. Through repeated iteration and convergence, an effect of filtering out the non-linear intermodulation product in the target signal can be increasingly better. This helps to improve the signal quality.

In a feasible implementation, the canceling and solving circuit may be specifically configured to: multiply the squared signal by the error eliminated signal, to obtain a cancellation component used to cancel out the non-linear intermodulation product; perform error solving processing on the target signal and the error eliminated signal, to obtain a coefficient value of the cancellation component; and multiply the coefficient value of the cancellation component by the cancellation component, to obtain the intermediate signal used to cancel out the non-linear intermodulation product, and input the intermediate signal to the addition circuit.

It should be clarified that, the intermediate signal may include two parts: the cancellation component and the coefficient value of the cancellation component. Through implementation of the foregoing feasible implementation, the canceling and solving circuit may solve an error between a signal before hard decision and a signal after the hard decision, obtain the coefficient value of the cancellation component based on the error, multiply the squared signal by the signal obtained after the hard decision, to obtain the cancellation component, and further obtain the intermediate signal, thereby solving the intermediate signal.

In a feasible implementation, the first signal processing branch includes; a filter circuit, a first power adjustment circuit, and a second analog-to-digital conversion circuit, where an input end of the filter circuit is coupled to the output end of the signal matching circuit, an output end of the filter circuit is coupled to an input end of the first power adjustment circuit, an output end of the first power adjustment circuit is coupled to an input end of the second analog-to-digital conversion circuit, and an output end of the second analog-to-digital conversion circuit is coupled to the input end of the second signal processing branch;

the filter circuit is configured to filter the first to-be-processed signal, to obtain a filtered signal; and input the filtered signal to the first power adjustment circuit;

the first power adjustment circuit is configured to perform power adjustment processing on the filtered signal and then input the filtered signal obtained after the power adjustment processing to the second analog-to-digital conversion circuit; and

the second analog-to-digital conversion circuit is configured to perform analog-to-digital conversion processing on the filtered signal obtained after the power adjustment processing, to obtain the interference canceled signal; and input the interference canceled signal to the second signal processing branch.

It can be learned that, through implementation of the foregoing feasible implementation, the filter circuit may filter the first to-be-processed signal, and after a part of an interfering signal is filtered out, subsequent processing is performed to convert the signal to the digital domain for processing, to cancel, together with the signal obtained by the second signal processing branch, the non-linear intermodulation product. The signal is divided into two branches for separate processing, so that processing efficiency of the signal processing apparatus can be improved.

In a feasible implementation, the signal matching circuit includes: a frequency mixing circuit, a signal amplification circuit, a second power adjustment circuit, and a coupling circuit, where an output end of the signal amplification circuit is coupled to an input end of the second power adjustment circuit, an output end of the second power adjustment circuit is coupled to an input end of the frequency mixing circuit, an output end of the frequency mixing circuit is coupled to an input end of the coupling circuit, and an output end of the coupling circuit is separately coupled to the input end of the first signal processing branch and the input end of the second signal processing branch;

the signal amplification circuit is configured to amplify the input signal, to obtain an amplified signal, and input the amplified signal to the second power adjustment circuit;

the second power adjustment circuit is configured to perform power adjustment processing on the amplified signal and input the amplified signal obtained after the power adjustment processing to the frequency mixing circuit;

the frequency mixing circuit is configured to adjust a frequency of the amplified signal obtained after the power adjustment processing to a preset frequency range, to obtain a mixed signal; and input the mixed signal to the coupling circuit; and

the coupling circuit is configured to couple the mixed signal, to separately obtain the first to-be-processed signal and the second to-be-processed signal; input the first to-be-processed signal to the first signal processing branch; and input the second to-be-processed signal to the second signal processing branch.

In a feasible implementation, the signal matching circuit includes: a frequency mixing circuit, a signal amplification circuit, a second power adjustment circuit, and a coupling circuit, where an output end of the signal amplification circuit is coupled to an input end of the coupling circuit, an output end of the coupling circuit is separately coupled to the input end of the second signal processing branch and an input end of the second power adjustment circuit, an output end of the second power adjustment circuit is coupled to an input end of the frequency mixing circuit, and an output end of the frequency mixing circuit is coupled to the input end of the first signal processing branch;

the signal amplification circuit is configured to amplify the input signal, to obtain an amplified signal; and input the amplified signal to the coupling circuit;

the coupling circuit is configured to couple the amplified signal, to obtain the second to-be-processed signal; and separately input the second to-be-processed signal to the second power adjustment circuit and the second signal processing branch;

the second power adjustment circuit is configured to perform power adjustment processing on the second to-be-processed signal and input the second to-be-processed signal obtained after the power adjustment processing to the frequency mixing circuit; and

the frequency mixing circuit is configured to adjust a frequency of the second to-be-processed signal obtained after the power adjustment processing to a preset frequency range, to obtain the first to-be-processed signal; and input the first to-be-processed signal to the second signal processing branch.

In a feasible implementation, the signal matching circuit includes: a frequency mixing circuit, a signal amplification circuit, a second power adjustment circuit, and a coupling circuit, where an output end of the signal amplification circuit is coupled to an input end of the second power adjustment circuit, an output end of the second power adjustment circuit is coupled to an input end of the coupling circuit, an output end of the coupling circuit is separately coupled to an input end of the frequency mixing circuit and the input end of the second signal processing branch, and an output end of the frequency mixing circuit is coupled to the input end of the first signal processing branch;

the signal amplification circuit is configured to amplify the input signal, to obtain an amplified signal; and input the amplified signal to the second power adjustment circuit;

the second power adjustment circuit is configured to perform power adjustment processing on the amplified signal and input the amplified signal obtained after the power adjustment processing to the coupling circuit;

the coupling circuit is configured to couple the amplified signal obtained after the power adjustment processing, to obtain the second to-be-processed signal; and separately input the second to-be-processed signal to the frequency mixing circuit and the second signal processing branch; and

the frequency mixing circuit is configured to adjust a frequency of the second to-be-processed signal to a preset frequency range, to obtain the first to-be-processed signal; and input the first to-be-processed signal to the second signal processing branch.

In a feasible implementation, the signal matching circuit includes: a frequency mixing circuit, a signal amplification circuit, a second power adjustment circuit, and a coupling circuit, where an output end of the coupling circuit is separately coupled to the input end of the second signal processing branch and an input end of the signal amplification circuit, an output end of the signal amplification circuit is coupled to an input end of the second power adjustment circuit, an output end of the second power adjustment circuit is coupled to an input end of the frequency mixing circuit, and an output end of the frequency mixing circuit is coupled to the input end of the first signal processing branch;

the coupling circuit is configured to couple the input signal, to obtain the second to-be-processed signal; and separately input the second to-be-processed signal to the second signal processing branch and the signal amplification circuit;

the signal amplification circuit is configured to amplify the second to-be-processed signal, to obtain an amplified signal; and input the amplified signal to the second power adjustment circuit;

the second power adjustment circuit is configured to perform power adjustment processing on the amplified signal and input the amplified signal obtained after the power adjustment processing to the frequency mixing circuit; and

the frequency mixing circuit is configured to adjust a frequency of the amplified signal obtained after the power adjustment processing to a preset frequency range, to obtain the first to-be-processed signal; and input the first to-be-processed signal to the second signal processing branch.

It can be learned that, through implementation of the foregoing feasible implementation, the coupling circuit in the signal matching circuit may be disposed at any location before the filter circuit, so that a magnitude-phase characteristic of a coupled signal can be applicable to subsequently solving of the intermediate signal, thereby resolving a problem that the signal cannot be used for subsequent canceling and solving processing because the magnitude-phase characteristic of the signal is severely damaged by the filter circuit after the signal passes through the filter circuit.

According to a second aspect, an embodiment of this application provides a signal processing method. The signal processing method is applied to a signal processing apparatus, and can implement a processing process in the signal processing apparatus according to any one of the first aspect or the possible implementations of the first aspect.

### BRIEF DESCRIPTION OF DRAWINGS

FIG. 1 is a schematic structural diagram of a signal processing apparatus according to an embodiment of this application;

FIG. 2 is a spectrum graph of an output signal according to an embodiment of this application;

FIG. 3 is a schematic structural diagram of a signal processing apparatus according to an embodiment of this application;

FIG. 4a is a schematic structural diagram of a signal matching circuit according to an embodiment of this application:

FIG. 4b is a schematic structural diagram of another signal matching circuit according to an embodiment of this application;

FIG. 4c is a schematic structural diagram of still another signal matching circuit according to an embodiment of this application:

FIG. 4d is a schematic structural diagram of yet another signal matching circuit according to an embodiment of this application;

FIG. 5 is a schematic structural diagram of a first signal processing branch according to an embodiment of this application:

FIG. 6 is a schematic structural diagram of a second signal processing branch according to an embodiment of this application;

FIG. 7 is a schematic structural diagram of a digital processing circuit according to an embodiment of this application;

FIG. 8 is a schematic structural diagram of another signal processing apparatus according to an embodiment of this application; and

FIG. 9 is a schematic flowchart of a signal processing method according to an embodiment of this application.

### DESCRIPTION OF EMBODIMENTS

The following correspondingly describes the technical solutions in the embodiments of this application with reference to the accompanying drawings in the embodiments of this application.

With continuous development of modern microwave communications technologies, communication environments become increasingly complex, and frequencies of signals are increasingly higher. There may be a plurality of microwave devices on a same tower, and different microwave devices may use different frequencies. In a process of transmitting signals, there is a relatively high possibility that signals transmitted by different microwave devices interfere with each other. This affects stability of a communication channel. For example, in a propagation process of signals of two or more frequencies, a non-linear intermodulation product of another frequency may be generated. The non-linear intermodulation product overlaps a wanted signal, severely reducing signal quality.

The non-linear intermodulation product may have a third-order component, a fifth-order component, a seventh-order component, or even a component of a higher order. A component of a third-order intermodulation product is the largest. For example, if a frequency of a wanted signal is f1, a frequency of an interfering signal is f2 (f2>f1), and a frequency difference between the wanted signal and the interfering signal is Δf=f2−f1, a frequency of the third-order intermodulation product may be between f2+Δf and f1−Δf. When the third-order intermodulation product falls in a frequency range of the wanted signal, the wanted signal may be severely distorted.

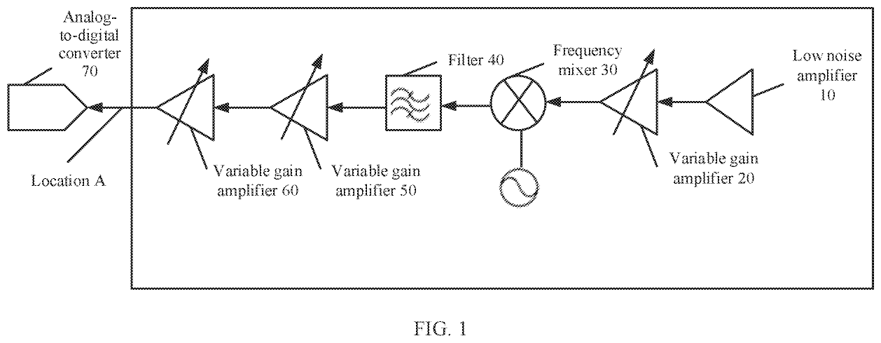

In an embodiment, the interfering signal may be suppressed by a filter. For example, FIG. 1 is a schematic structural diagram of a signal processing apparatus according to this application. The apparatus shown in FIG. 1 may include: a low noise amplifier 10, a variable gain amplifier 20, a frequency mixer 30, a filter 40, a variable gain amplifier 50, a variable gain amplifier 60, and an analog-to-digital converter 70.

Specifically, after an input signal is input to the low noise amplifier 10 for amplification, down-conversion of the signal may be implemented by the frequency mixer 30; and after the signal is filtered by the filter 40, power of the signal may be adjusted by the variable gain amplifier 50 and the variable gain amplifier 60, and then the signal is input to the analog-to-digital converter 70, so that a next device performs digital processing on the signal in a digital domain.

However, a signal amplitude of an interfering signal input to the low noise amplifier 10 is usually relatively large, the interfering signal and a wanted signal may affect each other in a previous device (for example, the frequency mixer 30) of the filter 40, and consequently, a non-linear intermodulation product is generated. The non-linear intermodulation product falls in a frequency band range of the wanted signal, and is in a same band with the wanted signal.

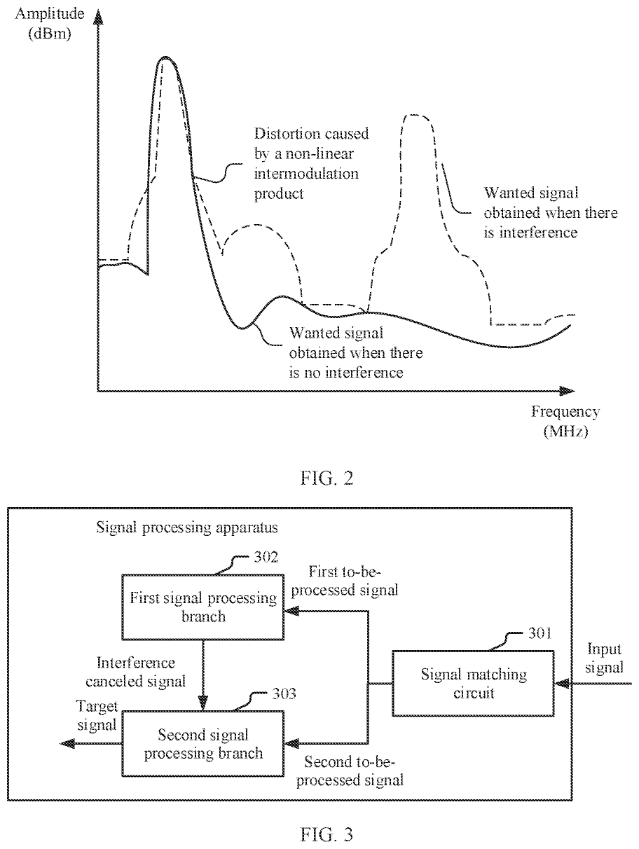

FIG. 2 is a spectrum graph of an output signal obtained through measurement at a location A (that is, a location between the variable gain amplifier 60 and the analog-to-digital converter 70) in FIG. 1. A solid line represents a wanted signal collected at the location A when there is no interference, and a dashed line represents a wanted signal collected at the location A when there is an interfering signal. It can be learned that, when there is the interfering signal, due to a non-linear characteristic of an analog receive channel, a non-linear intermodulation product is generated by using the interfering signal and the wanted signal. The non-linear intermodulation product may fall in a frequency band range of the wanted signal, and the non-linear intermodulation product cannot be suppressed by the filter 40. Due to frequency selectivity of the filter 40, the interfering signal is suppressed when passing through the filter 40, and power of the interfering signal approximates to that of the wanted signal. Actually, the power of the interfering signal input to the low noise amplifier 10 is far greater than that of the wanted signal.

It can be learned that, the filter cannot perform effective anti-interference processing on a signal, and a filtered signal is still relatively severely distorted.

To resolve the foregoing technical problem, this application further provides a signal processing apparatus, to resolve a problem that in a radio frequency communications system, a non-linear intermodulation product deteriorates signal quality when there is interference on a communications channel.

For ease of understanding, a main inventive principle of this application may include: a signal processing branch is disposed before a filter to collect envelope information of an interfering signal (in this case, the interfering signal is not suppressed by the filter, and the collected envelope information can be effectively used for subsequent digital sampling); then a signal used to cancel out a non-linear intermodulation product is constructed in a digital domain based on the envelope information; and the signal is synthesized with a signal filtered by the filter, to cancel out the non-linear intermodulation product, thereby improving signal quality.

It should be noted that, the foregoing principle is merely used for explanation, and should not constitute a limitation on this application.

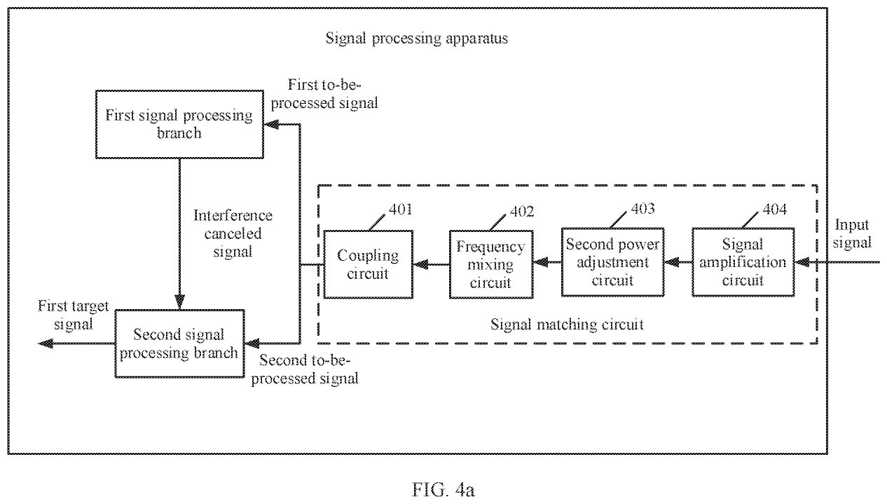

Based on the foregoing main inventive principle, FIG. 3 is a schematic structural diagram of another signal processing apparatus according to an embodiment of this application. It can be learned that, the signal processing apparatus in FIG. 3 may include: a signal matching circuit 301, a first signal processing branch 302, and a second signal processing branch 303.

In an embodiment, the signal processing apparatus may be disposed in a receive link of a microwave outdoor communications unit (ODU), or a receive link of a full outdoor communications unit (Full-ODU). This is not limited in this application.

An output end of the signal matching circuit 301 is separately coupled to an input end of the first signal processing branch 302 and an input end of the second signal processing branch 303, and an output end of the first signal processing branch 302 is coupled to the input end of the second signal processing branch 303.

The signal matching circuit 301 may be configured to: separately obtain a first to-be-processed signal and a second to-be-processed signal based on an input signal, input the first to-be-processed signal to the first signal processing branch 302, and input the second to-be-processed signal to the second signal processing branch 303.

In an embodiment, the input signal may be input by a previous device connected to the signal processing apparatus, and the input signal may include a wanted signal and an interfering signal, or may further include a non-linear intermodulation product generated when the wanted signal and the interfering signal affect each other.

In an embodiment, signal strength of the interfering signal may be far greater than signal strength of the wanted signal, a frequency of the interfering signal may be far higher than a frequency of the wanted signal, an amplitude of the interfering signal may be far larger than an amplitude of the wanted signal, or there may be another case. This is not limited in this application.

A coupling circuit may be disposed in the signal matching circuit 301. The signal is divided into two signals through the coupling circuit, and the two signals are respectively input to the first signal processing branch 302 for filtering processing and the second signal processing branch 303 for collecting envelope information.

In an embodiment, the signal matching circuit may include a frequency mixing circuit, a signal amplification circuit, and the coupling circuit. An output end of the signal amplification circuit is coupled to an input end of the frequency mixing circuit, an output end of the frequency mixing circuit is coupled to an input end of the coupling circuit, and an output end of the coupling circuit is separately coupled to the input end of the first signal processing branch and the input end of the second signal processing branch.

The signal amplification circuit is configured to amplify the input signal, to obtain an amplified signal, and input the amplified signal to the frequency mixing circuit. The frequency mixing circuit is configured to adjust a frequency of the amplified signal to a preset frequency range, to obtain a mixed signal, and input the mixed signal to the coupling circuit. The coupling circuit is configured to couple the mixed signal, to separately obtain the first to-be-processed signal and the second to-be-processed signal, input the first to-be-processed signal to the first signal processing branch, and input the second to-be-processed signal to the second signal processing branch.

In an embodiment, alternatively, the output end of the signal amplification circuit may be coupled to the input end of the coupling circuit, the output end of the coupling circuit is separately coupled to the input end of the second signal processing branch and the input end of the frequency mixing circuit, and the output end of the frequency mixing circuit is coupled to the input end of the first signal processing branch.

The signal amplification circuit is configured to amplify the input signal, to obtain an amplified signal, and input the amplified signal to the coupling circuit. The coupling circuit is configured to couple the amplified signal, to obtain the second to-be-processed signal, and separately input the second to-be-processed signal to the second signal processing branch and the frequency mixing circuit. The frequency mixing circuit is configured to adjust a frequency of the second to-be-processed signal to a preset frequency range, to obtain the first to-be-processed signal, and input the first to-be-processed signal to the first signal processing branch.

In an embodiment, alternatively, the output end of the coupling circuit may be separately coupled to the input end of the second signal processing branch and the input end of the signal amplification circuit, the output end of the signal amplification circuit is coupled to the input end of the frequency mixing circuit, and the output end of the frequency mixing circuit is coupled to the first signal processing branch.

The coupling circuit is configured to couple the input signal, to obtain the second to-be-processed signal, and separately input the second to-be-processed signal to the second signal processing branch and the signal amplification circuit. The signal amplification circuit is configured to amplify the second to-be-processed signal, to obtain an amplified signal, and input the amplified signal to the frequency mixing circuit. The frequency mixing circuit is configured to adjust a frequency of the amplified signal to a preset frequency range, to obtain the first to-be-processed signal, and input the first to-be-processed signal to the first signal processing branch.

In an embodiment, the signal matching circuit may alternatively include: a frequency mixing circuit, a signal amplification circuit, a second power adjustment circuit, and a coupling circuit.

The signal amplification circuit described in this application may be a low noise amplifier (LNA), so that the input signal is amplified while a relatively low noise factor is ensured. Because all subsequent circuits process the amplified signal passing through the signal amplification circuit, disposing an LNA with a low noise factor can ensure that a subsequent processing process is not affected by noise of the amplifier.

Alternatively, the signal amplification circuit described in this application may be a power amplifier (PA), a fiber amplifier (FA), a line amplifier (LA), or the like. This is not limited in this application.

The second power adjustment circuit described in this application may be a variable gain amplifier (VGA), a variable voltage amplifier (VVA), or a combination of the VVA and an amplifier. This is not limited in this application.

A core device of the frequency mixing circuit described in this application may be a frequency mixer, to implement frequency transformation. The frequency mixing circuit may be a single frequency conversion architecture, and only include one stage of frequency mixer, or is a super-heterodyne architecture, and includes a plurality of stages of frequency mixers; or there may be another case. This is not limited in this application.

The frequency mixer may directly process the amplified signal (which is a radio frequency signal) amplified by the signal amplification circuit, and perform frequency conversion on the amplified signal, to obtain the mixed signal. The frequency mixer may alternatively receive a local oscillation (LO) signal from a voltage-controlled oscillator, to implement a frequency mixing function.

The coupling circuit described in this application may be a coupler, a power splitter, or the like.

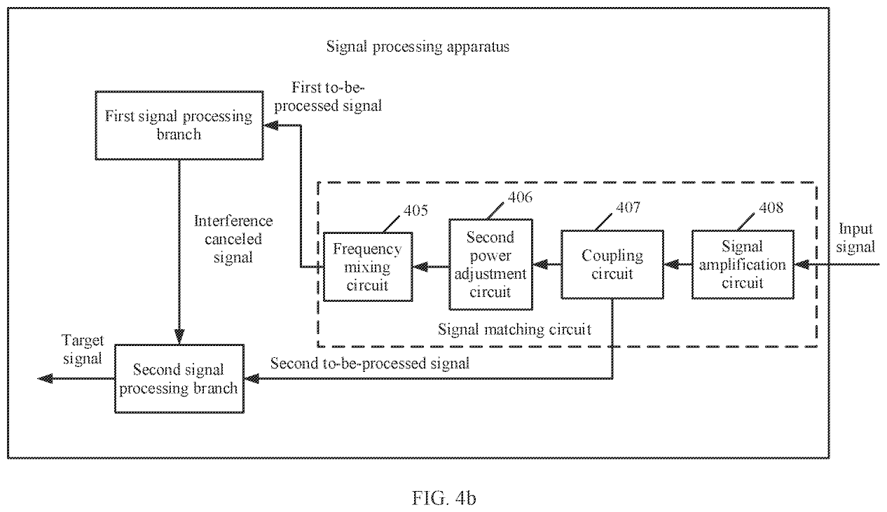

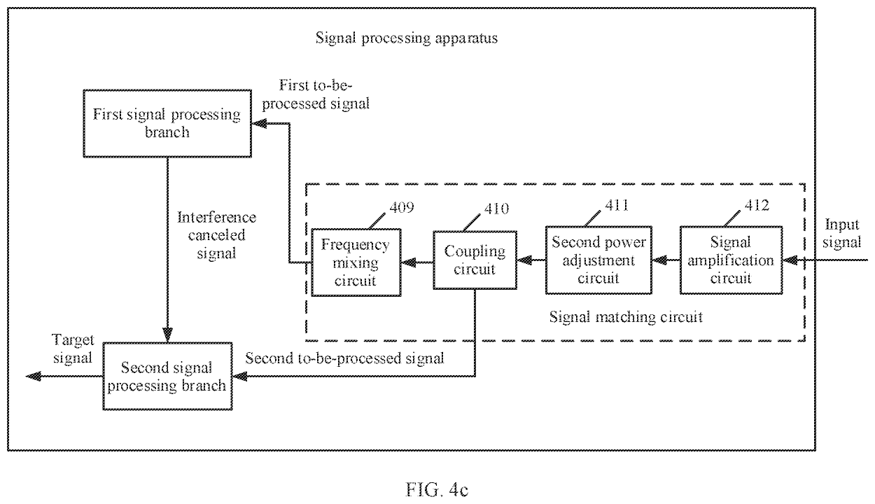

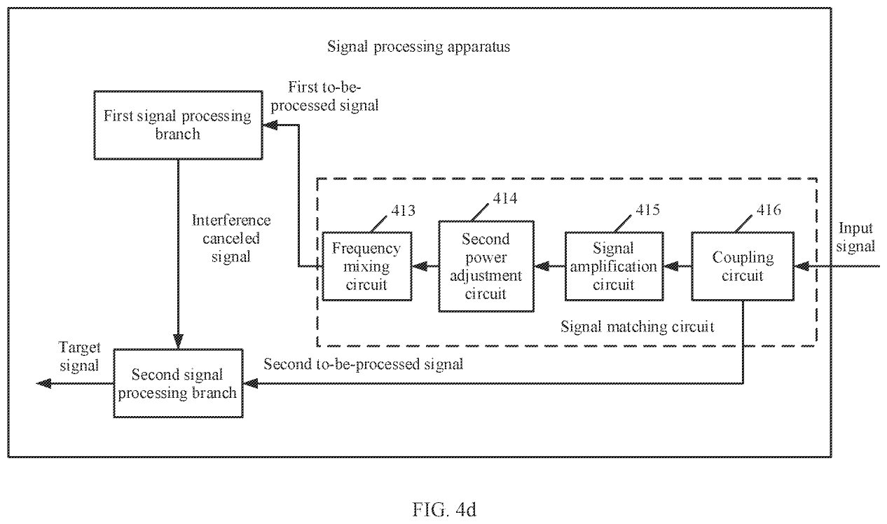

In an embodiment, FIG. 4a is a schematic structural diagram of a signal matching circuit according to this application. The signal matching circuit shown in FIG. 4a may include: a frequency mixing circuit 402, a signal amplification circuit 404, a second power adjustment circuit 403, and a coupling circuit 401. An output end of the signal amplification circuit 404 is coupled to an input end of the second power adjustment circuit 403, an output end of the second power adjustment circuit 403 is coupled to an input end of the frequency mixing circuit 402, an output end of the frequency mixing circuit 402 is coupled to an input end of the coupling circuit 401, and an output end of the coupling circuit 401 is separately coupled to the input end of the first signal processing branch and the input end of the second signal processing branch.

The signal amplification circuit 404 may be configured to amplify the input signal, to obtain an amplified signal; and input the amplified signal to the second power adjustment circuit 403.

The second power adjustment circuit 403 is configured to perform power adjustment processing on the amplified signal and input the amplified signal obtained after the power adjustment processing to the frequency mixing circuit 402. Specifically, the second power adjustment circuit 403 may perform power adjustment on the amplified signal, to ensure that power of the signal input to a next device is in a preset range, and that the signal can be processed by the lower-level device.

The frequency mixing circuit 402 may be configured to adjust a frequency of the amplified signal obtained after the power adjustment processing to a preset frequency range, to obtain a mixed signal; and input the mixed signal to the coupling circuit 401.

The coupling circuit 401 may be configured to couple the mixed signal, to separately obtain the first to-be-processed signal and the second to-be-processed signal; input the first to-be-processed signal to the first signal processing branch; and input the second to-be-processed signal to the second signal processing branch. The first to-be-processed signal and the second to-be-processed signal may be two same signals. After being coupled by the coupling circuit 401, the signal input to the coupling circuit 401 may be duplicated, to obtain the two same signals.

In another embodiment, referring to FIG. 4b, a signal matching circuit may include: a frequency mixing circuit 405, a second power adjustment circuit 406, a coupling circuit 407, and a signal amplification circuit 408. An output end of the signal amplification circuit 408 is coupled to an input end of the coupling circuit 407, an output end of the coupling circuit 407 is separately coupled to the input end of the second signal processing branch and an input end of the second power adjustment circuit 406, an output end of the second power adjustment circuit 406 is coupled to an input end of the frequency mixing circuit 405, and an output end of the frequency mixing circuit 405 is coupled to the input end of the first signal processing branch.

The signal amplification circuit 408 may be configured to amplify the input signal, to obtain an amplified signal; and input the amplified signal to the coupling circuit 407.

The coupling circuit 407 may be configured to couple the amplified signal, to obtain the second to-be-processed signal; and separately input the second to-be-processed signal to the second power adjustment circuit 406 and the second signal processing branch.

The second power adjustment circuit 406 is configured to perform power adjustment processing on the second to-be-processed signal and input the second to-be-processed signal obtained after the power adjustment processing to the frequency mixing circuit 405.

The frequency mixing circuit 405 is configured to adjust a frequency of the second to-be-processed signal obtained after the power adjustment processing to a preset frequency range, to obtain the first to-be-processed signal; and input the first to-be-processed signal to the first signal processing branch.

It should be noted that, the first to-be-processed signal and the second to-be-processed signal that are generated by the signal matching circuit shown in FIG. 4b are different. The first to-be-processed signal is a signal obtained after the frequency mixing circuit 405 adjusts, after the power adjustment processing is performed on the second to-be-processed signal, the frequency of the second to-be-processed signal.

In still another embodiment, referring to FIG. 4c, a signal matching circuit shown in FIG. 4c may include: a frequency mixing circuit 409, a signal amplification circuit 412, a second power adjustment circuit 411, and a coupling circuit 410.

An output end of the signal amplification circuit 412 is coupled to an input end of the second power adjustment circuit 411, an output end of the second power adjustment circuit 411 is coupled to an input end of the coupling circuit 410, an output end of the coupling circuit 410 is separately coupled to an input end of the frequency mixing circuit 409 and the input end of the second signal processing branch, and an output end of the frequency mixing circuit 409 is coupled to the input end of the first signal processing branch.

The signal amplification circuit 412 may be configured to amplify the input signal, to obtain an amplified signal; and input the amplified signal to the second power adjustment circuit 411.

The second power adjustment circuit 411 may be configured to perform power adjustment processing on the amplified signal and input the amplified signal obtained after the power adjustment processing to the coupling circuit 410.

The coupling circuit 410 may be configured to couple the amplified signal obtained after the power adjustment processing, to obtain the second to-be-processed signal, and separately input the second to-be-processed signal to the frequency mixing circuit 409 and the second signal processing branch.

The frequency mixing circuit 409 may be configured to adjust a frequency of the second to-be-processed signal to a preset frequency range, to obtain the first to-be-processed signal, and input the first to-be-processed signal to the first signal processing branch.

It should be noted that, the first to-be-processed signal and the second to-be-processed signal that are generated by the signal matching circuit shown in FIG. 4c are different. The first to-be-processed signal is a signal obtained after the frequency mixing circuit 410 adjusts the frequency of the second to-be-processed signal.

In still another embodiment, referring to FIG. 4d, a signal matching circuit shown in FIG. 4d may include: a frequency mixing circuit 413, a second power adjustment circuit 414, a signal amplification circuit 415, and a coupling circuit 416. An output end of the coupling circuit 416 is separately coupled to the input end of the second signal processing branch and an input end of the signal amplification circuit 415, an output end of the signal amplification circuit 415 is coupled to an input end of the second power adjustment circuit 414, an output end of the second power adjustment circuit 414 is coupled to an input end of the frequency mixing circuit 413, and an output end of the frequency mixing circuit 413 is coupled to the input end of the first signal processing branch.

The coupling circuit 416 may be configured to couple the input signal, to obtain the second to-be-processed signal, and separately input the second to-be-processed signal to the second signal processing branch and the signal amplification circuit 415.

It should be noted that, the coupling circuit 416 couples the input signal, to obtain two same signals. That is, the two obtained second to-be-processed signals may be the same as the input signal.

The signal amplification circuit 415 may be configured to amplify the second to-be-processed signal, to obtain an amplified signal, and input the amplified signal to the second power adjustment circuit 414.

The second power adjustment circuit 414 may be configured to perform power adjustment processing on the amplified signal and input the amplified signal obtained after the power adjustment processing to the frequency mixing circuit 413.

The frequency mixing circuit 413 may be configured to adjust a frequency of the amplified signal obtained after the power adjustment processing to a preset frequency range, to obtain the first to-be-processed signal, and input the first to-be-processed signal to the first signal processing branch.

It should be noted that, the first to-be-processed signal and the second to-be-processed signal that are generated by the signal matching circuit shown in FIG. 4d are different. The second to-be-processed signal may be the same as the input signal, and the first to-be-processed signal may be a signal obtained after the signal amplification processing, the power adjustment processing, and the frequency mixing processing are performed on the second to-be-processed signal.

The first signal processing branch 302 may be configured to filter the first to-be-processed signal, to obtain an interference canceled signal, and input the interference canceled signal to the second signal processing branch 303, where the interference canceled signal includes a non-linear intermodulation product.

For example, the first to-be-processed signal may include the wanted signal, the interfering signal, and the non-linear intermodulation product. The first signal processing branch 302 filters the first to-be-processed signal, and filters out the interfering signal in a manner of frequency selection, to obtain the interference canceled signal including the non-linear intermodulation product.

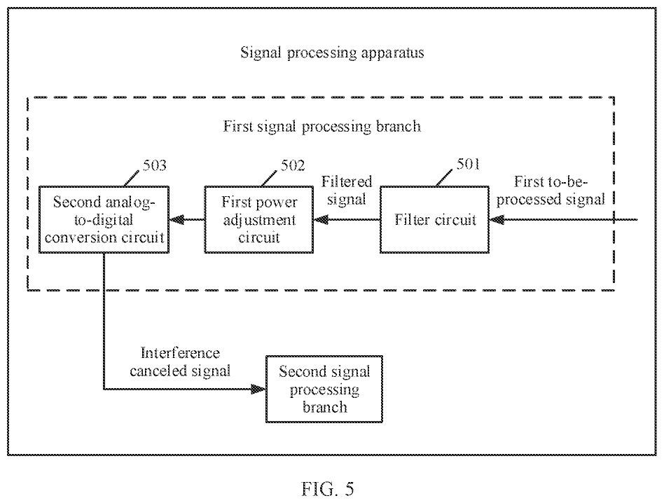

In an embodiment, FIG. 5 is a schematic structural diagram of a first signal processing branch according to an embodiment of this application. The first signal processing branch shown in FIG. 5 may include: a filter circuit 501, a first power adjustment circuit 502, and a second analog-to-digital conversion circuit 503. An input end of the filter circuit 501 is coupled to the output end of the signal matching circuit, an output end of the filter circuit 501 is coupled to an input end of the first power adjustment circuit 502, an output end of the first power adjustment circuit 502 is coupled to an input end of the second analog-to-digital conversion circuit 503, and an output end of the second analog-to-digital conversion circuit 503 is coupled to the input end of the second signal processing branch.

The filter circuit 501 may be configured to filter the first to-be-processed signal, to obtain a filtered signal, and input the filtered signal to the first power adjustment circuit 502.

In an embodiment, the filter circuit 501 may be a filter, and specifically, may be a band-pass filter, a high-pass filter, a low-pass filter, a band-rejection filter, or the like. This is not limited in this application.

For example, a frequency selection range may be preset for the filter circuit 501. A frequency of the interfering signal is not in the frequency selection range. When the first to-be-processed signal is input, the filter circuit 501 may filter out the interfering signal based on the frequency selection range, to obtain the filtered signal that is filtered.

The first power adjustment circuit 502 is configured to perform power adjustment processing on the filtered signal and then input the filtered signal obtained after the power adjustment processing to the second analog-to-digital conversion circuit 503.

In an embodiment, the first power adjustment circuit 502 may be a VGA.

In an embodiment, one, two, or even more, first power adjustment circuit 502 may be disposed. Gain adjustment is performed on the filtered signal through the plurality of first power adjustment circuits 502, to further adjust a signal level, thereby ensuring that the next device can work normally.

The second analog-to-digital conversion circuit 503 is configured to perform analog-to-digital conversion processing on the filtered signal obtained after the power adjustment processing, to obtain the interference canceled signal, and input the interference canceled signal to the second signal processing branch.

In an embodiment, the second analog-to-digital conversion circuit 503 may be an analog to digital converter (ADC).

The second analog-to-digital conversion circuit 503 may convert the filtered signal from an analog signal into a digital signal, and the digital signal obtained through the conversion is the interference canceled signal.

The second signal processing branch 303 may be configured to collect envelope information in the second to-be-processed signal, and generate, based on the envelope information and the interference canceled signal, a target signal in which the non-linear intermodulation product is canceled out.

The second to-be-processed signal may include the wanted signal, the interfering signal, and the non-linear intermodulation product. The signal strength of the interfering signal may be far greater than the signal strength of the wanted signal. Therefore, the collected envelope information in the second to-be-processed signal may be approximately the same as envelope information of the interfering signal. The interfering signal before the filtering may be restored by using the envelope information of the interfering signal. Algorithm correction is performed through the interfering signal before the filtering, to calculate the generated non-linear intermodulation product, and an intermediate signal used to cancel out the non-linear intermodulation product is generated based on a calculation result. Then, the interference canceled signal is canceled out by using the intermediate signal, to obtain the target signal in which the non-linear intermodulation product is filtered out, so that a problem of signal distortion is alleviated.

It can be learned that, in this embodiment of this application, the signal matching circuit performs preliminary processing on the input signal, to obtain the first to-be-processed signal and the second to-be-processed signal; and the first signal processing branch filters the first to-be-processed signal, to obtain interference canceled information. The second signal processing branch collects the envelope information in the second to-be-processed signal that is not filtered, and cancels out the non-linear intermodulation product canceled based on the envelope information and the interference canceled signal, to obtain the target signal. In this way, effective anti-interference processing is performed on the non-linear intermodulation product to some extent, thereby improving signal quality.

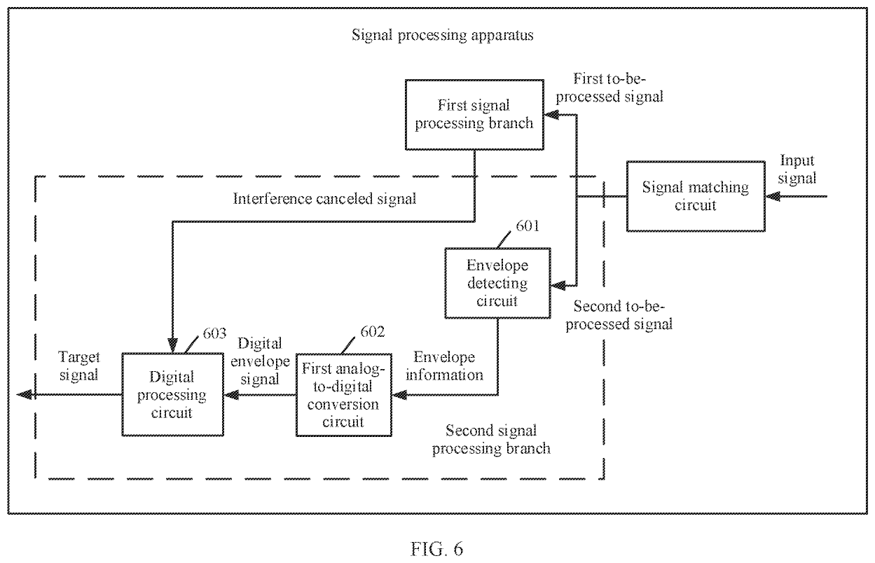

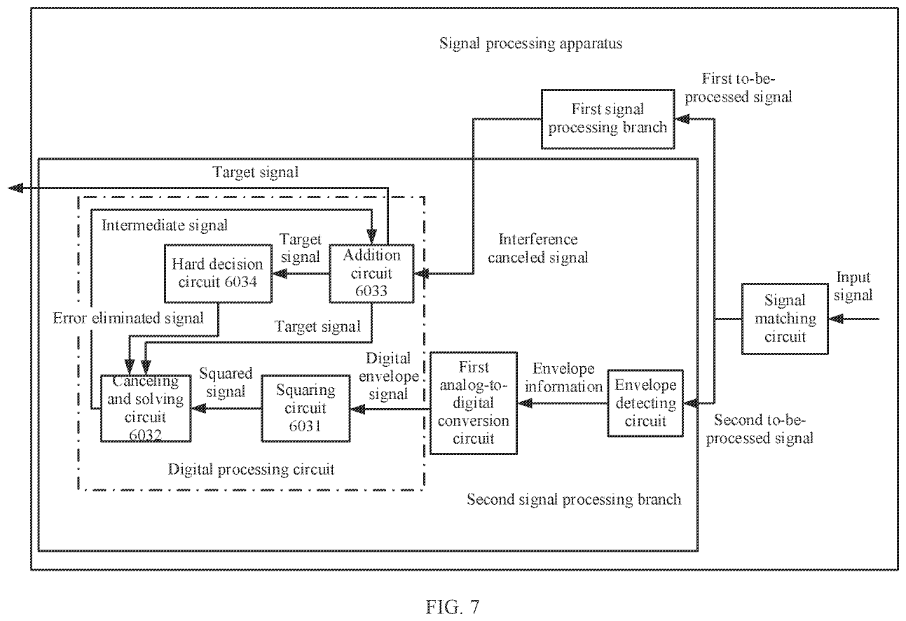

FIG. 6 is a schematic structural diagram of a second signal processing branch according to this application. The second signal processing branch shown in FIG. 6 may include: an envelope detecting circuit 601, a first analog-to-digital conversion circuit 602, and a digital processing circuit 603. The output end of the signal matching circuit is coupled to an input end of the envelope detecting circuit 601, an output end of the envelope detecting circuit 601 is coupled to an input end of the first analog-to-digital conversion circuit 602, and an output end of the first analog-to-digital conversion circuit 602 and the output end of the first signal processing branch are separately coupled to an input end of the digital processing circuit 603.

The envelope detecting circuit 601 is configured to collect the envelope information in the second to-be-processed signal, and input the envelope information to the first analog-to-digital conversion circuit 602.

In an embodiment, the envelope detecting circuit 601 may be an envelope detecting tube. For example, the envelope detecting tube may perform signal information extraction on the second to-be-processed signal, to demodulate the second to-be-processed signal to obtain a low frequency signal, where the low frequency signal obtained through demodulation includes useful information (such as an amplitude) in the second to-be-processed signal. This process may be referred to as collecting the envelope information in the second to-be-processed signal.

The first analog-to-digital conversion circuit 602 is configured to perform first analog-to-digital conversion processing based on the envelope information, to obtain a digital envelope signal; and input the digital envelope signal to the digital processing circuit 603.

In an embodiment, the first analog-to-digital conversion circuit 602 may be an ADC. For example, after the envelope detecting circuit inputs the envelope information to the ADC, the ADC may convert the envelope information from an analog domain to a digital domain, to obtain the digital envelope signal.

The digital processing circuit 603 is configured to obtain, based on the interference canceled signal and the digital envelope signal, the target signal in which the non-linear intermodulation product is canceled out.

In an embodiment, the digital processing circuit 603 may be integrated in an American standard code for information interchange (ASCII) chip, a digital signal processing (DSP) chip, a field programmable gate array (FPGA) chip, or the like, and is configured to obtain, based on the interference canceled signal and the digital envelope signal, the target signal in which the non-linear intermodulation product is canceled out.

In an embodiment, FIG. 7 is a schematic structural diagram of a digital processing circuit according to this application. The digital processing circuit shown in FIG. 7 may specifically include: a squaring circuit 6031, a canceling and solving circuit 6032, an addition circuit 6033, and a hard decision circuit 6034. The output end of the first analog-to-digital conversion circuit is coupled to an input end of the squaring circuit 6031; an output end of the squaring circuit 6031, an output end of the hard decision circuit 6034, and an output end of the addition circuit 6033 are separately coupled to an input end of the canceling and solving circuit 6032; an output end of the canceling and solving circuit 6032 and the output end of the first signal processing branch are separately coupled to an input end of the addition circuit 6033; and the output end of the addition circuit 6033 is coupled to an input end of the hard decision circuit 6034.

The addition circuit 6033 is configured to separately input a target signal to the canceling and solving circuit 6032 and the hard decision circuit 6034.

It should be clarified that, a signal generated by the addition circuit 6033 is the target signal.

The hard decision circuit 6034 is configured to perform error eliminating processing on the target signal based on a preset threshold condition, to obtain an error eliminated signal; and input the error eliminated signal to the canceling and solving circuit 6032.

For example, the hard decision circuit may pre-estimate a point cloud diagram of an ideal signal (where the point cloud diagram includes amplitudes and phase relationships of all points in the estimated ideal signal). Distances between the points may be the same. The preset threshold may be a value obtained by dividing a distance between two adjacent points by 2. That is, the preset threshold may be a center value of a distance between two adjacent points. When the target signal is received, a point a in the target signal may be compared with a corresponding point a′ in the estimated ideal signal. If a distance difference between the point a and the point a′ is less than the preset threshold, it may be determined that the point a can represent the point a′ in the ideal signal. If a distance difference between the point a and the point a′ is greater than the preset threshold, it may be determined that the point a cannot represent the point a′ in the ideal signal. Some errors may be eliminated by comparing all points in the target signal with corresponding points in the estimated ideal signal.

The squaring circuit 6031 is configured to square the digital envelope signal, to obtain a squared signal; and input the squared signal to the canceling and solving circuit 6032.

The canceling and solving circuit 6032 is configured to obtain, based on the squared signal, the target signal, and the error eliminated signal, the intermediate signal used to cancel out the non-linear intermodulation product; and input the intermediate signal to the addition circuit 6033.

In an embodiment, the canceling and solving circuit 6032 is specifically configured to: multiply the squared signal by the error eliminated signal, to obtain a cancellation component used to cancel out the non-linear intermodulation product; perform error solving processing on the target signal and the error eliminated signal, to obtain a coefficient value of the cancellation component; and multiply the coefficient value of the cancellation component by the cancellation component, to obtain the intermediate signal used to cancel out the non-linear intermodulation product, and input the intermediate signal to the addition circuit 6033.

For example, the intermediate signal used to cancel out the non-linear intermodulation product may include two parts: the cancellation component and the coefficient value of the cancellation component. The cancellation component is obtained by multiplying a square (that is, the squared signal) of a modulus value of the digital envelope signal by a hard decision signal, and an error between the hard decision signal and the target signal before the hard decision is solved. Then the coefficient value of the cancellation component is solved based on the error between the hard decision signal and the target signal before the hard decision, and the coefficient value of the cancellation component is multiplied by the cancellation component, to obtain the intermediate signal.

A smaller error between the hard decision signal and the target signal before the hard decision indicates a smaller difference between the coefficient value of the cancellation component and an optimal value, and therefore indicates a better effect of canceling out the non-linear interference intermodulation product.

The addition circuit 6033 is further configured to obtain, based on the interference canceled signal and the intermediate signal, the target signal in which the non-linear intermodulation product is canceled out.

It should be noted that, as long as the signal processing apparatus is working, input signals may be continuously input to the signal processing apparatus. Therefore, when the signal processing apparatus starts to work, the first signal processing branch generates the interference canceled signal, the squaring circuit 6031 generates the squared signal, the canceling and solving circuit 6032 inputs the squared signal as the intermediate signal to the addition circuit 6033, and the addition circuit 6033 generates the target signal based on the intermediate signal and the interference canceled signal. However, in this case, an effect of canceling out an interference intermodulation product in the target signal is relatively poor. In this case, the addition circuit 6033 inputs the target signal to the hard decision circuit 6034 and the canceling and solving circuit 6032, so that the hard decision circuit 6034 performs error elimination on the target signal, to obtain the error eliminated signal, and inputs the error eliminated signal to the canceling and solving circuit 6032. The canceling and solving circuit 6032 then performs canceling and solving based on the received target signal, error eliminated signal, and squared signal, to obtain the intermediate signal used to cancel out the non-linear intermodulation product. The addition circuit 6033 may perform synthesis based on the intermediate signal and the received interference canceled signal, to obtain the target signal in which the non-linear intermodulation product is canceled out.

In an embodiment, after the target signal in which the non-linear intermodulation product is canceled out is obtained, the addition circuit 6033 may further input the target signal in which the non-linear intermodulation product is canceled out to the hard decision circuit 6034 and the canceling and solving circuit 6032, to perform next signal processing. Through repeated iteration and convergence, an effect of filtering out the non-linear intermodulation product in the target signal can be increasingly better.

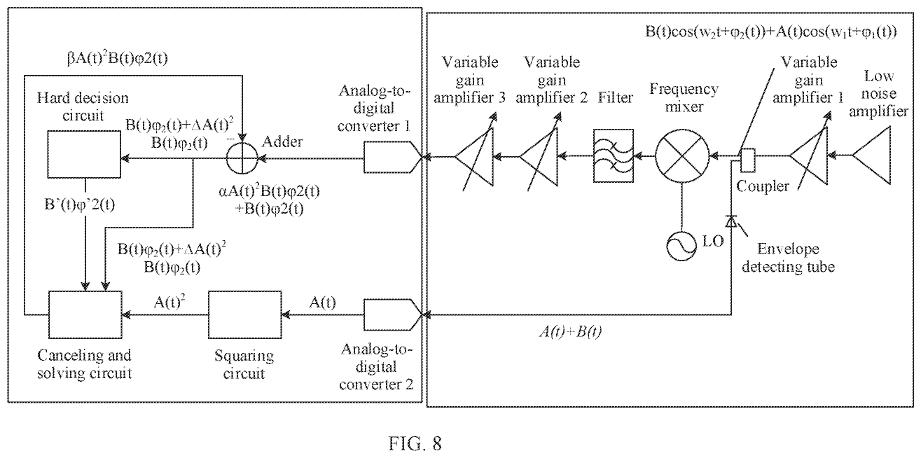

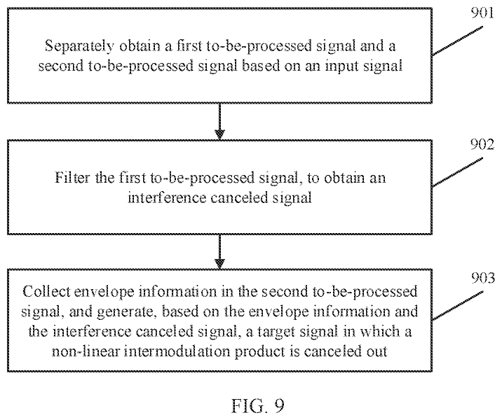

For clearer description, FIG. 8 is a schematic structural diagram of another signal processing apparatus according to this application. The signal processing apparatus shown in FIG. 8 may be a specific example of the foregoing signal processing apparatus. However, it should be learned that, in another feasible implementation, there may alternatively be another example of the signal processing apparatus, and this is not limited in this application.

The signal processing apparatus shown in FIG. 8 may include: a low noise amplifier, a variable gain amplifier 1, a frequency mixer, a variable gain amplifier 2, a variable gain amplifier 3, an analog-to-digital converter 1, an adder, a hard decision circuit, a canceling and solving circuit, a squaring circuit, an analog-to-digital converter 2, an envelope detecting tube, and a coupler.

After the low noise amplifier amplifies an input signal, the variable gain amplifier 1 may first perform power adjustment, to obtain a power adjusted signal, to ensure that the power of a signal received by a next device is in a preset power range, and may match the next device. Specifically, the power adjusted signal may be represented as B(t)cos(w₂t+φ₂(t))+A(t)cos(w₁t+φ₁(t)), where B(t)cos(w₂t+φ₂(t)) may represent a wanted signal, and A(t)cos(w₁t+φ₁(t)) may represent an interfering signal, and A(t) is far greater than B(t).

B(t) may represent amplitude information of the wanted signal, w₂t may represent carrier information of the wanted signal, and φ₂(t) may represent phase information of the wanted signal. Similarly, A(t) may represent amplitude information of the interfering signal, w₁t may represent carrier information of the interfering signal, and φ₁(t) may represent phase information of the interfering signal.

The power adjusted signal is input to the coupler, and is coupled by the coupler, to obtain two same signals, where the two same signals may also be represented as B(t)cos(w₂t+φ₂(t))+A(t)cos(w₁t+φ₁(t)). One of the two signals is input to the frequency mixer, and the other signal is input to the envelope detecting tube.

Frequency mixing processing may be performed on the signal input to the frequency mixer and an LO signal from a voltage-controlled oscillator, to obtain a mixed signal. The mixed signal is then input to a filter for filtering processing, to obtain a filtered signal. After the variable gain amplifier 2 and the variable gain amplifier 3 implement power adjustment on the filtered signal, to ensure that power of the filtered signal obtained after the power adjustment matches a next device, the filtered signal obtained after the power adjustment is input to the analog-to-digital converter 1, and is converted into an interference canceled signal in a digital domain. In this case, an expression of the interference canceled signal may be B(t)φ₂(t).

The envelope detecting tube may collect envelope information in the signal input to the envelope detecting tube, where the envelope information may be amplitude information of the signal, and may be represented as A(t)+B(t). Then the analog-to-digital converter 2 performs analog-to-digital conversion processing on the envelope information, to obtain a digital envelope signal. An expression of the digital envelope signal may also be A(t)+B(t). Because A(t) is far greater than B(t), the digital envelope signal may also be written as A(t). The digital envelope signal is input to the squaring circuit, and a modulus value of the digital envelope signal is squared, to obtain a squared signal, where an expression of the squared signal may be A(t)².

Before this processing, a target signal obtained by an addition circuit may be represented as B(t)φ₂(t)+ΔA(t)²B(t)φ₂(t), where A(t)²B(t)φ₂(t) may represent a non-linear intermodulation product, and A may represent a ratio coefficient of the non-linear intermodulation product. The addition circuit separately input the target signal to the hard decision circuit and the canceling and solving circuit. The hard decision circuit may perform error eliminating processing on the target signal based on a preset threshold, to obtain an error eliminated signal, where the error eliminated signal may be represented as B′(t)φ′₂(t).

The canceling and solving circuit may multiply the squared signal A(t)² by the error eliminated signal B′(t)φ′₂(t), to obtain a cancellation component, namely, A(t)²B(t)φ₂(t). The canceling and solving circuit may further solve a coefficient value R of the cancellation component based on an error ΔA(t)²B(t)φ₂(t) between the error eliminated signal B′(t)φ′₂(t) obtained after hard decision and the target signal B(t)φ₂(t)+ΔA(t)²B(t)φ₂(t) before the hard decision. The canceling and solving circuit multiplies the coefficient value β of the cancellation component by the cancellation component A(t)²B(t)φ₂(t), to obtain an intermediate signal βA(t)²B(t)φ₂(t), and inputs the intermediate signal to the adder. A smaller error between the target signal before the hard decision and the error eliminated signal after the hard decision indicates a smaller difference between the coefficient value β of the cancellation component and an optimal value α, and therefore indicates a better effect of canceling out the interference intermodulation product.

The adder may synthesize the intermediate signal βA(t)²B(t)φ₂(t) with the interference canceled signal B(t)φ₂(t), to obtain a target signal βA(t)²B(t)φ₂(t)+B(t)φ₂(t) in which the non-linear interference product is filtered out.

Further, the adder may input the target signal βA(t)²B(t)φ₂(t)+B(t)φ₂(t) to the hard decision circuit and the canceling and solving circuit again, to continuously optimize the coefficient value β through the canceling and solving circuit, so that the coefficient value β is closer to the optimal value α. In this way, a finally obtained target signal can be αA(t)²B(t)φ₂(t)+B(t)φ₂(t). In this case, the effect of filtering out the non-linear interference product is relatively good.

It can be learned that, in this embodiment of this application, an envelope detecting circuit is integrated. The envelope detecting circuit collects envelope information of a second to-be-processed signal, the canceling and solving circuit generates the intermediate signal used to cancel out the non-linear intermodulation product, and an addition circuit synthesizes the intermediate signal with the interference canceled signal, to cancel out the non-linear intermodulation product in the digital domain, thereby obtaining the target signal, so that effective anti-interference processing can be performed on the non-linear intermodulation product, and signal quality is improved.

FIG. 9 is a schematic flowchart of a signal processing method according to this application. It should be noted that, the signal processing method may be applied to the foregoing signal processing apparatus. Specifically, the signal processing method shown in FIG. 9 may include the following steps.

901. Separately obtain a first to-be-processed signal and a second to-be-processed signal based on an input signal.

It should be noted that, a signal matching circuit in a signal processing apparatus may separately obtain the first to-be-processed signal and the second to-be-processed signal based on the input signal.

In an embodiment, the separately obtaining a first to-be-processed signal and a second to-be-processed signal based on an input signal includes: amplifying the input signal, to obtain an amplified signal; performing power adjustment processing on the amplified signal, and adjusting a frequency of the amplified signal obtained after the power adjustment processing to a preset frequency range, to obtain a mixed signal; and coupling the mixed signal, to separately obtain the first to-be-processed signal and the second to-be-processed signal.

In an embodiment, the separately obtaining a first to-be-processed signal and a second to-be-processed signal based on an input signal includes: amplifying the input signal, to obtain an amplified signal; coupling the amplified signal, to obtain the second to-be-processed signal; and performing power adjustment processing on the second to-be-processed signal, and adjusting a frequency of the second to-be-processed signal obtained after the power adjustment processing to a preset frequency range, to obtain the first to-be-processed signal.

In an embodiment, the separately obtaining a first to-be-processed signal and a second to-be-processed signal based on an input signal includes: amplifying the input signal, to obtain an amplified signal; performing power adjustment processing on the amplified signal, and coupling the amplified signal obtained after the power adjustment processing, to obtain the second to-be-processed signal; and adjusting a frequency of the second to-be-processed signal to a preset frequency range, to obtain the first to-be-processed signal.

In an embodiment, the separately obtaining a first to-be-processed signal and a second to-be-processed signal based on an input signal includes: coupling the input signal, to obtain the second to-be-processed signal; amplifying the second to-be-processed signal, to obtain an amplified signal; and performing power adjustment processing on the amplified signal, and adjusting a frequency of the amplified signal obtained after the power adjustment processing to a preset frequency range, to obtain the first to-be-processed signal.

902. Filter the first to-be-processed signal, to obtain an interference canceled signal.

It should be noted that, a first signal processing branch in the signal processing apparatus may filter the first to-be-processed signal, to obtain the interference canceled signal.

The interference canceled signal includes a non-linear intermodulation product.

In an embodiment, the filtering the first to-be-processed signal, to obtain an interference canceled signal includes: filtering the first to-be-processed signal, to obtain a filtered signal; and performing power adjustment processing on the filtered signal, and performing analog-to-digital conversion processing on the filtered signal obtained after the power adjustment processing, to obtain the interference canceled signal.

903. Collect envelope information in the second to-be-processed signal, and generate, based on the envelope information and the interference canceled signal, a target signal in which the non-linear intermodulation product is canceled out.

It should be noted that, a second signal processing branch in the signal processing apparatus may collect the envelope information in the second to-be-processed signal, and generate, based on the envelope information and the interference canceled signal, the target signal in which the non-linear intermodulation product is canceled out.

In an embodiment, the collecting envelope information in the second to-be-processed signal, and generating, based on the envelope information and the interference canceled signal, a target signal in which the non-linear intermodulation product is canceled out includes: collecting the envelope information in the second to-be-processed signal; performing first analog-to-digital conversion processing based on the envelope information, to obtain a digital envelope signal; and obtaining, based on the interference canceled signal and the digital envelope signal, the target signal in which the non-linear intermodulation product is canceled out.

In an embodiment, the obtaining, based on the interference canceled signal and the digital envelope signal, the target signal in which the non-linear intermodulation product is canceled out includes: performing error eliminating processing on a target signal based on a preset threshold condition, to obtain an error eliminated signal; squaring the digital envelope signal, to obtain a squared signal; obtaining, based on the squared signal, the target signal, and the error eliminated signal, an intermediate signal used to cancel out the non-linear intermodulation product; and obtaining, based on the interference canceled signal and the intermediate signal, the target signal in which the non-linear intermodulation product is canceled out.

In an embodiment, the obtaining, based on the squared signal, the target signal, and the error eliminated signal, an intermediate signal used to cancel out the non-linear intermodulation product includes: multiplying the squared signal by the error eliminated signal, to obtain a cancellation component used to cancel out the non-linear intermodulation product; performing error solving processing on the target signal and the error eliminated signal, to obtain a coefficient value of the cancellation component; and multiplying the coefficient value of the cancellation component by the cancellation component, to obtain the intermediate signal used to cancel out the non-linear intermodulation product.

It should be noted that, the signal processing method described in this application may be applied to the foregoing signal processing apparatus, and the descriptions of the processing procedure of the signal processing apparatus may also be applicable to the signal processing method. Details are not described herein again.

A person of ordinary skill in the art may understand that all or some of the steps of the methods in the embodiments may be implemented by a program instructing related hardware. The program may be stored in a computer-readable storage medium. The storage medium may include a flash memory, a read-only memory (ROM), a random-access memory (RAM), a magnetic disk, an optical disk, or the like.

The signal processing apparatus and the signal processing method that are provided in the embodiments of this application are described in detail above. The principle and implementation of this application are described herein through specific examples. The descriptions about the embodiments of this application are merely provided to help understand the structure, the method, and the core ideas of this application. In addition, a person of ordinary skill in the art can make variations to this application in terms of the specific implementations and application scopes according to the ideas of this application. Therefore, the content of this specification shall not be construed as a limit to this application.

What is claimed is:

1. A signal processing apparatus, comprising: a signal matching circuit, a first signal processing branch, and a second signal processing branch, wherein:
an output end of the signal matching circuit is separately coupled to an input end of the first signal processing branch and an input end of the second signal processing branch, wherein an output end of the first signal processing branch is coupled to the input end of the second signal processing branch;
the signal matching circuit is configured to:
separately obtain a first to-be-processed signal and a second to-be-processed signal based on an input signal;
input the first to-be-processed signal to the first signal processing branch; and
input the second to-be-processed signal to the second signal processing branch;
the first signal processing branch is configured to:
filter the first to-be-processed signal to obtain an interference canceled signal; and
input the interference canceled signal to the second signal processing branch, wherein the interference canceled signal comprises a non-linear intermodulation product; and
the second signal processing branch is configured to:
collect envelope information in the second to-be-processed signal; and
generate, based on the envelope information and the interference canceled signal, a target signal in which the non-linear intermodulation product is canceled out.

2. The apparatus according to claim 1, wherein the second signal processing branch comprises: an envelope detecting circuit, a first analog-to-digital conversion circuit, and a digital processing circuit, wherein:
the output end of the signal matching circuit is coupled to an input end of the envelope detecting circuit;
an output end of the envelope detecting circuit is coupled to an input end of the first analog-to-digital conversion circuit; and
an output end of the first analog-to-digital conversion circuit and the output end of the first signal processing branch are separately coupled to an input end of the digital processing circuit;
the envelope detecting circuit is configured to:
collect the envelope information in the second to-be-processed signal; and
input the envelope information to the first analog-to-digital conversion circuit;
the first analog-to-digital conversion circuit is configured to:
perform first analog-to-digital conversion processing based on the envelope information to obtain a digital envelope signal; and
input the digital envelope signal to the digital processing circuit; and
the digital processing circuit is configured to obtain, based on the interference canceled signal and the digital envelope signal, the target signal in which the non-linear intermodulation product is canceled out.

3. The apparatus according to claim 2, wherein the digital processing circuit comprises: a squaring circuit, a canceling and solving circuit, an addition circuit, and a hard decision circuit; wherein:
the output end of the first analog-to-digital conversion circuit is coupled to an input end of the squaring circuit;
an output end of the squaring circuit, an output end of the hard decision circuit, and an output end of the addition circuit are separately coupled to an input end of the canceling and solving circuit;
an output end of the canceling and solving circuit and the output end of the first signal processing branch are separately coupled to an input end of the addition circuit;
the output end of the addition circuit is coupled to an input end of the hard decision circuit;
the addition circuit is configured to separately input a target signal to the canceling and solving circuit and the hard decision circuit;
the hard decision circuit is configured to:
perform error eliminating processing on the target signal based on a preset threshold condition to obtain an error eliminated signal; and
input the error eliminated signal to the canceling and solving circuit:
the squaring circuit is configured to:
square the digital envelope signal to obtain a squared signal; and
input the squared signal to the canceling and solving circuit;
the canceling and solving circuit is configured to:
obtain, based on the squared signal, the target signal, and the error eliminated signal, an intermediate signal used to cancel out the non-linear intermodulation product; and
input the intermediate signal to the addition circuit; and
the addition circuit is further configured to obtain, based on the interference canceled signal and the intermediate signal, the target signal in which the non-linear intermodulation product is canceled out.

4. The apparatus according to claim 3, wherein the canceling and solving circuit is configured to:
multiply the squared signal by the error eliminated signal to obtain a cancellation component used to cancel out the non-linear intermodulation product;
perform error solving processing on the target signal and the error eliminated signal to obtain a coefficient value of the cancellation component;
multiply the coefficient value of the cancellation component by the cancellation component to obtain the intermediate signal used to cancel out the non-linear intermodulation product; and
input the intermediate signal to the addition circuit.

5. The apparatus according to claim 1, wherein the first signal processing branch comprises:
a filter circuit, a first power adjustment circuit, and a second analog-to-digital conversion circuit, wherein:
an input end of the filter circuit is coupled to the output end of the signal matching circuit;
an output end of the filter circuit is coupled to an input end of the first power adjustment circuit;
an output end of the first power adjustment circuit is coupled to an input end of the second analog-to-digital conversion circuit;
an output end of the second analog-to-digital conversion circuit is coupled to the input end of the second signal processing branch;
the filter circuit is configured to:
filter the first to-be-processed signal to obtain a filtered signal; and
input the filtered signal to the first power adjustment circuit;
the first power adjustment circuit is configured to:
perform power adjustment processing on the filtered signal; and
input the filtered signal obtained after the power adjustment processing to the second analog-to-digital conversion circuit; and
the second analog-to-digital conversion circuit is configured to:
perform analog-to-digital conversion processing on the filtered signal obtained after the power adjustment processing to obtain the interference canceled signal; and
input the interference canceled signal to the second signal processing branch.

6. The apparatus according to claim 1, wherein the signal matching circuit comprises: a frequency mixing circuit, a signal amplification circuit, a second power adjustment circuit, and a coupling circuit, wherein:
an output end of the signal amplification circuit is coupled to an input end of the second power adjustment circuit;
an output end of the second power adjustment circuit is coupled to an input end of the frequency mixing circuit;
an output end of the frequency mixing circuit is coupled to an input end of the coupling circuit;
an output end of the coupling circuit is separately coupled to the input end of the first signal processing branch and the input end of the second signal processing branch;
the signal amplification circuit is configured to:
amplify the input signal, to obtain an amplified signal; and
input the amplified signal to the second power adjustment circuit;
the second power adjustment circuit is configured to:
perform power adjustment processing on the amplified signal; and
input the amplified signal obtained after the power adjustment processing to the frequency mixing circuit;
the frequency mixing circuit is configured to:
adjust a frequency of the amplified signal obtained after the power adjustment processing to a preset frequency range to obtain a mixed signal; and
input the mixed signal to the coupling circuit; and
the coupling circuit is configured to:
couple the mixed signal to separately obtain the first to-be-processed signal and the second to-be-processed signal;
input the first to-be-processed signal to the first signal processing branch; and
input the second to-be-processed signal to the second signal processing branch.

7. The apparatus according to claim 1, wherein the signal matching circuit comprises: a frequency mixing circuit, a signal amplification circuit, a second power adjustment circuit, and a coupling circuit, wherein:
an output end of the signal amplification circuit is coupled to an input end of the coupling circuit;
an output end of the coupling circuit is separately coupled to the input end of the second signal processing branch and an input end of the second power adjustment circuit;
an output end of the second power adjustment circuit is coupled to an input end of the frequency mixing circuit;
an output end of the frequency mixing circuit is coupled to the input end of the first signal processing branch;
the signal amplification circuit is configured to:
amplify the input signal to obtain an amplified signal; and
input the amplified signal to the coupling circuit;
the coupling circuit is configured to:
couple the amplified signal to obtain the second to-be-processed signal; and
separately input the second to-be-processed signal to the second power adjustment circuit and the second signal processing branch:
the second power adjustment circuit is configured to:
perform power adjustment processing on the second to-be-processed signal; and
input the second to-be-processed signal obtained after the power adjustment processing to the frequency mixing circuit; and
the frequency mixing circuit is configured to:
adjust a frequency of the second to-be-processed signal obtained after the power adjustment processing to a preset frequency range to obtain the first to-be-processed signal; and
input the first to-be-processed signal to the first signal processing branch.

8. The apparatus according to claim 1, wherein the signal matching circuit comprises: a frequency mixing circuit, a signal amplification circuit, a second power adjustment circuit, and a coupling circuit, wherein:
an output end of the signal amplification circuit is coupled to an input end of the second power adjustment circuit;
an output end of the second power adjustment circuit is coupled to an input end of the coupling circuit;
an output end of the coupling circuit is separately coupled to an input end of the frequency mixing circuit and the input end of the second signal processing branch;
an output end of the frequency mixing circuit is coupled to the input end of the first signal processing branch;
the signal amplification circuit is configured to:
amplify the input signal to obtain an amplified signal; and
input the amplified signal to the second power adjustment circuit;
the second power adjustment circuit is configured to:
perform power adjustment processing on the amplified signal; and
input the amplified signal obtained after the power adjustment processing to the coupling circuit;
the coupling circuit is configured to:
couple the amplified signal obtained after the power adjustment processing to obtain the second to-be-processed signal; and
separately input the second to-be-processed signal to the frequency mixing circuit and the second signal processing branch; and
the frequency mixing circuit is configured to:
adjust a frequency of the second to-be-processed signal to a preset frequency range to obtain the first to-be-processed signal; and
input the first to-be-processed signal to the first signal processing branch.

9. The apparatus according to claim 1, wherein the signal matching circuit comprises: a frequency mixing circuit, a signal amplification circuit, a second power adjustment circuit, and a coupling circuit, wherein:
an output end of the coupling circuit is separately coupled to the input end of the second signal processing branch and an input end of the signal amplification circuit;
an output end of the signal amplification circuit is coupled to an input end of the second power adjustment circuit;
an output end of the second power adjustment circuit is coupled to an input end of the frequency mixing circuit;
an output end of the frequency mixing circuit is coupled to the input end of the first signal processing branch;
the coupling circuit is configured to:
couple the input signal to obtain the second to-be-processed signal; and
separately input the second to-be-processed signal to the second signal processing branch and the signal amplification circuit:
the signal amplification circuit is configured to:
amplify the second to-be-processed signal to obtain an amplified signal; and
input the amplified signal to the second power adjustment circuit;
the second power adjustment circuit is configured to:
perform power adjustment processing on the amplified signal; and
input the amplified signal obtained after the power adjustment processing to the frequency mixing circuit; and
the frequency mixing circuit is configured to:
adjust a frequency of the amplified signal obtained after the power adjustment processing to a preset frequency range to obtain the first to-be-processed signal; and
input the first to-be-processed signal to the first signal processing branch.

10. A signal processing method, comprising:
separately obtaining a first to-be-processed signal and a second to-be-processed signal based on an input signal;
filtering the first to-be-processed signal to obtain an interference canceled signal, wherein the interference canceled signal comprises a non-linear intermodulation product;
collecting envelope information in the second to-be-processed signal; and
generating, based on the envelope information and the interference canceled signal, a target signal in which the non-linear intermodulation product is canceled out.

11. The method according to claim 10, wherein the collecting envelope information in the second to-be-processed signal, and generating, based on the envelope information and the interference canceled signal, a target signal in which the non-linear intermodulation product is canceled out comprises:
collecting the envelope information in the second to-be-processed signal;
performing first analog-to-digital conversion processing based on the envelope information to obtain a digital envelope signal; and
obtaining, based on the interference canceled signal and the digital envelope signal, the target signal in which the non-linear intermodulation product is canceled out.

12. The method according to claim 11, wherein the obtaining, based on the interference canceled signal and the digital envelope signal, the target signal in which the non-linear intermodulation product is canceled out comprises:
performing error eliminating processing on a target signal based on a preset threshold condition to obtain an error eliminated signal;
squaring the digital envelope signal to obtain a squared signal;
obtaining, based on the squared signal, the target signal, and the error eliminated signal, an intermediate signal used to cancel out the non-linear intermodulation product; and
obtaining, based on the interference canceled signal and the intermediate signal, the target signal in which the non-linear intermodulation product is canceled out.

13. The method according to claim 12, wherein the obtaining, based on the squared signal, the target signal, and the error eliminated signal, an intermediate signal used to cancel out the non-linear intermodulation product comprises:
multiplying the squared signal by the error eliminated signal to obtain a cancellation component used to cancel out the non-linear intermodulation product;
performing error solving processing on the target signal and the error eliminated signal to obtain a coefficient value of the cancellation component; and
multiplying the coefficient value of the cancellation component by the cancellation component to obtain the intermediate signal used to cancel out the non-linear intermodulation product.

14. The method according to claim 10, wherein the filtering the first to-be-processed signal to obtain an interference canceled signal comprises:
filtering the first to-be-processed signal to obtain a filtered signal;
performing power adjustment processing on the filtered signal; and
performing analog-to-digital conversion processing on the filtered signal obtained after the power adjustment processing to obtain the interference canceled signal.

15. The method according to claim 10, wherein the separately obtaining a first to-be-processed signal and a second to-be-processed signal based on an input signal comprises:
amplifying the input signal to obtain an amplified signal;
performing power adjustment processing on the amplified signal;
adjusting a frequency of the amplified signal obtained after the power adjustment processing to a preset frequency range to obtain a mixed signal; and
coupling the mixed signal, to separately obtain the first to-be-processed signal and the second to-be-processed signal.

16. The method according to claim 10, wherein the separately obtaining a first to-be-processed signal and a second to-be-processed signal based on an input signal comprises:
amplifying the input signal to obtain an amplified signal;
coupling the amplified signal to obtain the second to-be-processed signal;
performing power adjustment processing on the second to-be-processed signal; and
adjusting a frequency of the second to-be-processed signal obtained after the power adjustment processing to a preset frequency range to obtain the first to-be-processed signal.

17. The method according to claim 10, wherein the separately obtaining a first to-be-processed signal and a second to-be-processed signal based on an input signal comprises:
amplifying the input signal to obtain an amplified signal;
performing power adjustment processing on the amplified signal;
coupling the amplified signal obtained after the power adjustment processing to obtain the second to-be-processed signal; and
adjusting a frequency of the second to-be-processed signal to a preset frequency range to obtain the first to-be-processed signal.

18. The method according to claim 10, wherein the separately obtaining a first to-be-processed signal and a second to-be-processed signal based on an input signal comprises:
coupling the input signal to obtain the second to-be-processed signal;
amplifying the second to-be-processed signal to obtain an amplified signal;
performing power adjustment processing on the amplified signal; and
adjusting a frequency of the amplified signal obtained after the power adjustment processing to a preset frequency range to obtain the first to-be-processed signal.
